(19) United States
(12) Patent Application Publication
(10) Pub. No.: US 2022/0384445 A1
(43) Pub. Date: Dec. 1, 2022

(54) METHOD FOR MANUFACTURING MEMORY AND MEMORY

(71) Applicant: CHANGXIN MEMORY TECHNOLOGIES, INC., Hefei City (CN)

(72) Inventors: Qiang WAN, Hefei (CN); Jun XIA, Hefei (CN); Kangshu ZHAN, Hefei (CN); Tao LIU, Hefei (CN); Penghui XU, Hefei (CN); Sen LI, Hefei (CN)

(21) Appl. No.: 17/516,807

(22) Filed: Nov. 2, 2021

Related U.S. Application Data
(63) Continuation of application No. PCT/CN2021/111438, filed on Aug. 9, 2021.

(30) Foreign Application Priority Data
May 26, 2021 (CN) 202110579258.1

(51) Int. Cl. H01L 27/108

(52) U.S. Cl. CPC H01L 27/1085

(57) ABSTRACT

The disclosure provides a method for manufacturing a memory and the memory. The method includes that a laminated structure is formed on a substrate, in which the laminated structure comprises sacrificial layers and supporting layers arranged alternately, a top layer of the laminated structure is a supporting layer, and a supporting layer between two sacrificial layers is provided with intermediate holes filled with a sacrificial material; capacitor holes penetrating through the laminated structure are formed; a first polar plates are formed on the hole walls and the hole bottoms of the capacitor holes; areas corresponding to the intermediate holes in the supporting layer located on the top layer of the laminated structure are removed to form capacitor opening holes, which exposes a sacrificial layer; and all the sacrificial layers and all the sacrificial material are removed through the capacitor opening holes.

### CROSS-REFERENCE TO RELATED APPLICATIONS

The application is a continuation application of International Application No. PCT/CN2021/111438, filed on Aug. 9, 2021, which claims priority to Chinese Patent Application No. 202110579258.1, filed on May 26, 2021. The disclosures of International Application No. PCT/CN2021/111438 and Chinese Patent Application No. 202110579258.1 are hereby incorporated by reference in their entireties.

### BACKGROUND

A Dynamic Random Access Memory (DRAM) is a semiconductor memory for randomly writing in and reading data at high speed, and is widely applied to a data storage apparatus or device. The DRAM may usually include a capacitor, which stores data by storing charges.

In the related art, when a memory is manufactured, a laminated structure is usually formed on a substrate at first. The laminated structure may include supporting layers and sacrificial layers located between adjacent supporting layers; then, capacitor holes are formed in the laminated structure, and first polar plates are formed on the hole walls and the hole bottoms of a capacitor holes; then, parts of the top layer of supporting layer is removed to form capacitor opening holes, which expose a sacrificial layer; and then, the sacrificial layers are removed to conveniently form dielectric layer and second polar plates in the capacitor holes and at the position where the sacrificial layers are removed.

When the laminated structure may include a plurality of sacrificial layers, each sacrificial layer is located between two adjacent supporting layers. In the process of removing the sacrificial layers, a plurality of supporting layers need to be removed, the supporting layers usually need a relatively long time of pickling to reduce defects, the first polar plates are easy to be damaged during pickling of the supporting layers, and the yield of the memory is reduced.

### SUMMARY

The disclosure relates to the technical field of storage devices, and in particular relates to a method for manufacturing a memory and the memory.

The embodiment of the disclosure provides a method for manufacturing a memory, which includes the following operations. A laminated structure is formed on a substrate, in which the laminated structure may include sacrificial layers and supporting layers arranged alternately, a number of the sacrificial layers is greater than 1, a top layer of the laminated structure is a supporting layer, and a supporting layer between two sacrificial layers is provided with intermediate holes filled with a sacrificial material; part of the laminated structure is removed to form capacitor holes penetrating through the laminated structure; first polar plates are formed on hole walls and hole bottoms of the capacitor holes; areas corresponding to the intermediate holes in the supporting layer of the top layer of the laminated structure are removed to form capacitor opening holes, which expose a sacrificial layer; and all the sacrificial layers and all the sacrificial material in all the intermediate holes are removed through the capacitor opening holes to expose peripheral surfaces of the first polar plates.

The embodiment of the disclosure also provides a memory. The memory is manufactured by the method for manufacturing the memory described above.

### BRIEF DESCRIPTION OF THE DRAWINGS

FIG. 1 is a schematic structural diagram after part of a third supporting layer is removed in the related art.

FIG. 2 is a schematic structural diagram after a second sacrificial layer is removed in the related art.

FIG. 3 is a schematic structural diagram after a second supporting layer is removed in the related art.

FIG. 4 is a schematic structural diagram after a first sacrificial layer is removed in the related art.

FIG. 5 is a flowchart of a method for manufacturing a memory according to an embodiment of the disclosure.

FIG. 6 is a schematic structural diagram after a laminated structure is formed according to an embodiment of the disclosure.

FIG. 7 is a schematic structural diagram after a second photoresist layer is formed according to an embodiment of the disclosure.

FIG. 8 is the top view of FIG. 7.

FIG. 9 is a schematic structural diagram after capacitor holes are formed according to an embodiment of the disclosure.

FIG. 10 is the top view of FIG. 9.

FIG. 11 is a schematic structural diagram after first polar plates are formed according to an embodiment of the disclosure.

FIG. 12 is a schematic structural diagram after a third photoresist layer is formed according to an embodiment of the disclosure.

FIG. 13 is a schematic structural diagram after capacitor opening holes are formed according to an embodiment of the disclosure.

FIG. 14 is a schematic structural diagram after a sacrificial layer is removed according to an embodiment of the disclosure.

FIG. 15 is a flowchart that a laminated structure is formed according to an embodiment of the disclosure.

FIG. 16 is a schematic structural diagram after a first photoresist layer is formed according to an embodiment of the disclosure.

FIG. 17 is the top view of FIG. 16.

FIG. 18 is a schematic structural diagram after intermediate holes are formed according to an embodiment of the disclosure.

FIG. 19 is a schematic structural diagram after a sacrificial material is deposited according to an embodiment of the disclosure.

FIG. 20 is a schematic structural diagram after a sacrificial material on a second supporting layer is removed according to an embodiment of the disclosure.

### DETAILED DESCRIPTION

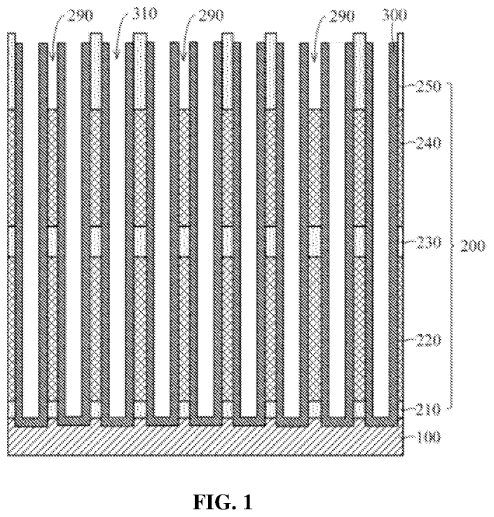

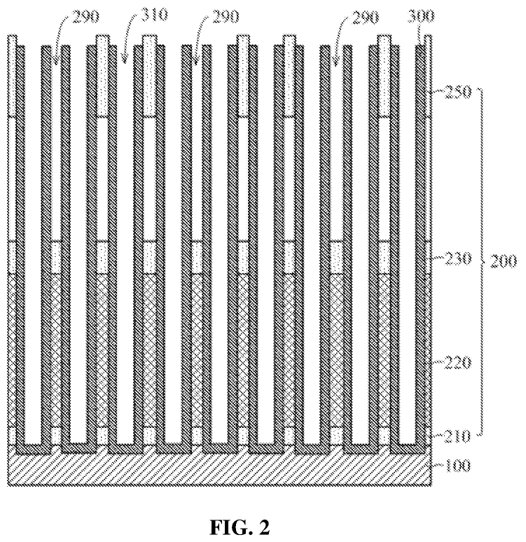

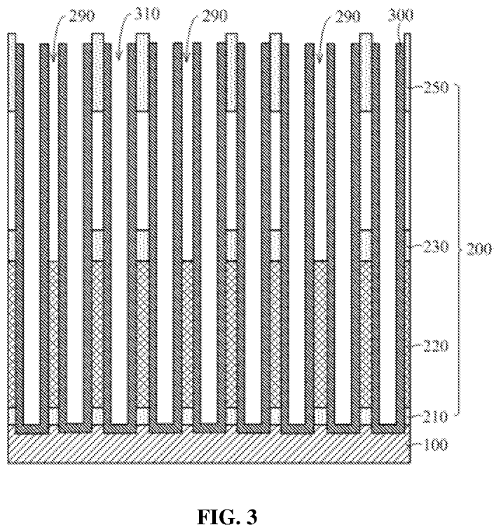

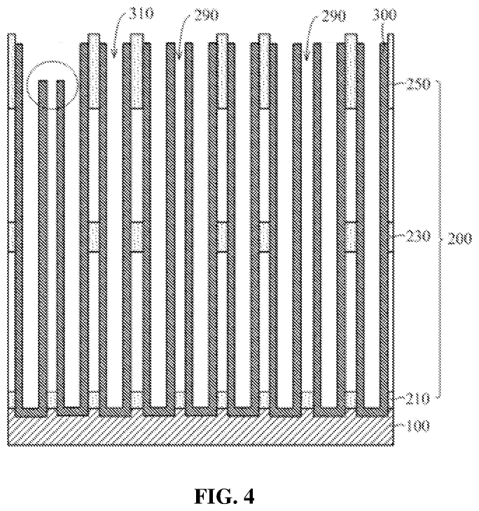

Referring to FIG. 1 to FIG. 4, in the related art, when a first sacrificial layer 220 and a second sacrificial layer 240 in a laminated structure 200 are removed after first polar plates 300 are formed, as shown in FIG. 1, capacitor opening holes 290 are usually formed in a third supporting layer 250 on the top layer of the laminated structure 200 at first; then, as shown in FIG. 2, after the whole second sacrificial layer 240 is removed by using the capacitor opening holes 290 which expose a second supporting layer 230; then, as shown in FIG. 3, the second supporting layer 230 exposed in the capacitor opening holes 290 is removed; and as shown in FIG. 4, the whole first sacrificial layer 220 is removed by using the capacitor opening holes 290. However, in the above process, the third supporting layer 250, the second sacrificial layer 240, the second supporting layer 230 and the first sacrificial layer are removed alternately, and an etching process needs to be continuously switched. Moreover, the removal of the third supporting layer 250 and the second supporting layer 230 usually requires a relatively long time of pickling, especially, when the second supporting layer 230 is pickled, therefore it is easy to damage the first polar plates 300.

In view of the above, the embodiment of the disclosure provides a method for manufacturing a memory. A supporting layer between two adjacent sacrificial layers is provided with intermediate holes, and the intermediate holes penetrate through the supporting layer and are filled with a sacrificial material. That is, the sacrificial material is in contact with the sacrificial layers, the sacrificial layers and the sacrificial material can be removed in a single etching process without opening supporting layers one by one. Therefore, the etching times and duration for removing the supporting layers after the formation of first polar plates are reduced, thereby reducing the possibility of damage to the first polar plates and improving the yield of the memory.

In order to make the above objectives, features and advantages of the embodiments of the disclosure more obvious and understandable, the technical solutions in the embodiments of the application will be clearly and completely described below in combination with the drawings in the embodiments of the disclosure. It is apparent that the described embodiments are not all embodiments but merely part of embodiments of the disclosure. On the basis of the embodiments of the disclosure, all other embodiments obtained by those of ordinary skilled in the art without creative work shall fall within the scope of protection of the disclosure.

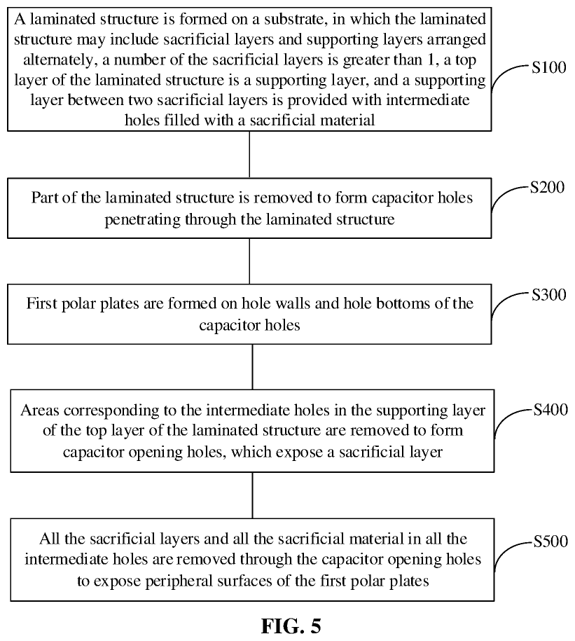

Referring to FIG. 5, FIG. 5 is a flowchart of a method for manufacturing a memory in the embodiment of the disclosure. The manufacturing method may include the following steps.

At S100, a laminated structure is formed on a substrate, the laminated structure may include sacrificial layers and supporting layers arranged alternately, herein, the number of the sacrificial layers is greater than 1, the top layer of the laminated structure is a supporting layer, and a supporting layer between two sacrificial layers is provided with intermediate holes filled with a sacrificial material.

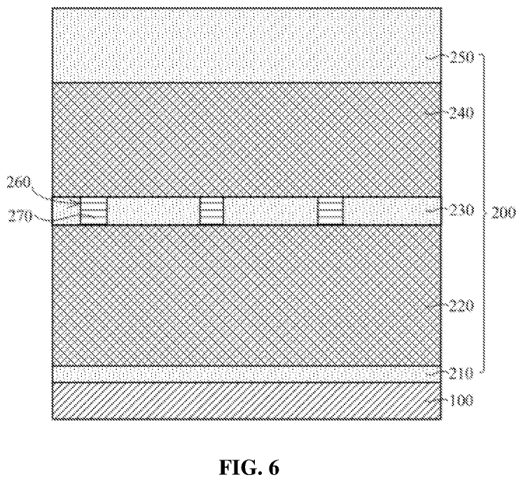

Referring to FIG. 6, the substrate 100 serves as a supporting part of the memory configured to support other parts arranged thereon. The substrate 100 may also include a capacitor contactor (not shown in the figure). A subsequently formed capacitor is electrically connected with the capacitor contactor, and the capacitor and a peripheral circuit are connected through the capacitor contactor, so that a voltage signal of the peripheral circuit can be transmitted to the capacitor to control charging and discharging of the capacitor.

As shown in FIG. 6, the laminated structure 200 is formed on the substrate 100, and the laminated structure 200 is configured to support the capacitor. The laminated structure 200 includes the sacrificial layers and the supporting layers. After the first polar plates of the capacitor are formed, the sacrificial layers and the sacrificial materials are removed to expose the peripheral surfaces of the first polar plates, and a supporting layer is retained to support the first polar plates and prevent the first polar plates from collapsing or contacting an adjacent first polar plate 300.

Continuously referring to FIG. 6, the sacrificial layers and the supporting layers are arranged alternately, the number of the sacrificial layers is at least two, and the top layer of the laminated structure 200 is a supporting layer. Herein, the top layer of the laminated structure 200 refers to an outer layer, away from the substrate 100, of the laminated structure 200. As shown in FIG. 6, the top layer of the laminated structure 200 refers to the uppermost layer of the laminated structure 200. Correspondingly, the layer in contact with the substrate 100 in the laminated structure 200 is the bottom layer of the laminated structure 200. In this way, the number of the supporting layers is also at least two, and arrangement of multiple supporting layers may increase the stability of the device. The material of the sacrificial layers may be silicon oxide (such as silicon dioxide), and the material of the supporting layers may be silicon nitride.

The sacrificial layers and the supporting layers may be formed by a deposition process. For example, after a sacrificial layer is deposited, a supporting layer is deposited on the sacrificial layer until the number of the sacrificial layers and the supporting layers reaches a preset value. The deposition process may be a Chemical Vapor Deposition (CVD) process, a Physical Vapor Deposition (PVD) process or an Atomic Layer Deposition (ALD) process.

In order to prevent the substrate 100 from being damaged when the laminated structure 200 is etched, the bottom layer of the laminated structure 200 may also be a supporting layer, that is, the layer in contact with the substrate 100 in the laminated structure 200 is also a supporting layer. As shown in FIG. 6, the outermost layers on the upper and lower sides of the laminated structure 200 are supporting layers, that is, the number of the supporting layers is greater than that of the sacrificial layers, and each sacrificial layer is arranged between two adjacent supporting layers. The supporting layer may be used as an etching barrier layer to protect the substrate 100.

Exemplarily, as shown in FIG. 6, the laminated structure 200 may include two sacrificial layers and three supporting layers, and a supporting layer, a sacrificial layer, a supporting layer, a sacrificial layer and a supporting layer are stacked in sequence. Or, the laminated structure 200 may include three sacrificial layers and four supporting layers, and a supporting layer, a sacrificial layer, a supporting layer, a sacrificial layer, a supporting layer, a sacrificial layer and a supporting layer are stacked in sequence.

Continuously referring to FIG. 6, the number of the sacrificial layers is greater than 1. The supporting layer located between the two sacrificial layers is provided with intermediate holes. An intermediate hole penetrates through the supporting layers and is filled with a sacrificial material 270. That is, the sacrificial material 270 is in contact with the two adjacent sacrificial layers, and the intermediate holes are used as a communication channel between the two adjacent sacrificial layers. When there are two sacrificial layers, the supporting layer located inside the laminated structure 200 is provided with intermediate holes. When there are three sacrificial layers, the two supporting layers located inside the laminated structure 200 are provided with intermediate holes, and projections of the intermediate holes arranged in different supporting layers may be superposed on the substrate.

The sacrificial material 270 fully fills the intermediate holes, and the etching rate selection ratio of the sacrificial material 270 to the sacrificial layers is 1. For example, the material of the sacrificial material 270 is the same as the material of the sacrificial layers, and that is, the sacrificial material 270 is silicon oxide. With this arrangement, all the sacrificial layers and all the sacrificial material 270 may be removed during once etching, thereby reducing the etching times of the sacrificial layers and improving the etching efficiency of the sacrificial layers.

In a possible example, as shown in FIG. 6, the laminated structure 200 may include two sacrificial layers and three supporting layers. For ease of description, two sacrificial layers are defined as the first sacrificial layer 220 and the second sacrificial layer 240 respectively, and three supporting layers are defined as a first supporting layer 210, a second supporting layer 230 and a third supporting layer 250 respectively. The first supporting layer 210, the first sacrificial layer 220, the second supporting layer 230, the second sacrificial layer 240 and the third supporting layer 250 are stacked. The first supporting layer 210 is arranged on the substrate 100, and the second supporting layer 230 is provided with intermediate holes 260.

At S200, part of the laminated structure is removed to form capacitor holes penetrating through the laminated structure.

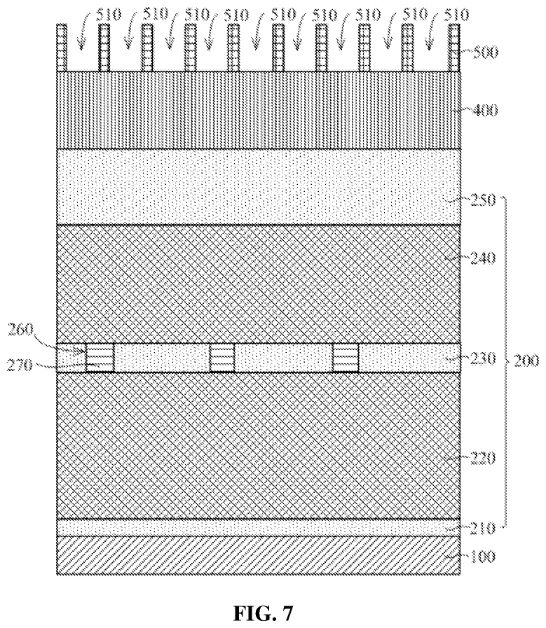

Referring to FIG. 7 to FIG. 10, the capacitor holes 280 are direct through holes, which penetrate through the laminated structure 200, and the substrate 100 is exposed in the capacitor holes 280. The capacitor holes 280 may be staggered from the intermediate holes 260, and that is, the sacrificial material 270 in the intermediate holes 260 is not removed in the process of forming the capacitor holes 280. The capacitor holes 280 may also be partially superposed with the intermediate holes 260 of each layer. Part of the hole walls of the capacitor holes 280 are located in the sacrificial material 270 in the intermediate holes. That is, part of the sacrificial material 270 in the intermediate holes is removed during the formation of the capacitor holes 280, and the sacrificial material 270 is also exposed in the capacitor holes 280.

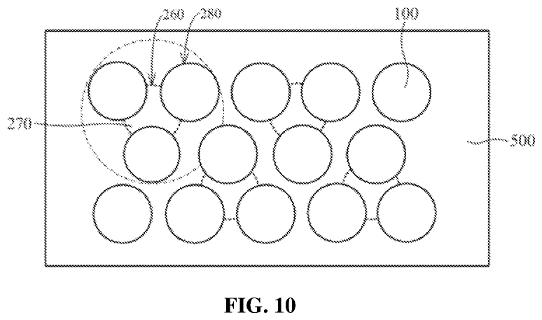

Exemplarily, referring to FIG. 10, there are multiple intermediate holes 260 located in a same supporting layer, three capacitor holes 280 are distributed in the circumferential direction of each intermediate hole, the three capacitor holes 280 are not communicated with each other, and the hole wall of a capacitor hole 280 extends into the sacrificial material.

In a dotted line frame shown in FIG. 10, the centers of the three capacitor holes 280 form a virtual triangle. The center of the intermediate hole 260 is superposed with the center of the virtual triangle, and the intermediate hole 260 is superposed with part of the area of each capacitor hole 280. After the capacitor holes 280 are formed, the outer contour of the remaining sacrificial material 270 is shown by a dotted line in FIG. 10, and the remaining sacrificial material 270 forms three concave areas in the circumferential direction.

In some possible examples, the operation that part of the laminated structure 200 is removed to form capacitor holes 280 penetrating through the laminated structure 200 may include the following operations.

Referring to FIG. 7, a second mask layer 400 is formed on the laminated structure 200. The second mask layer 400 may be a spin on hardmask (SOH) layer. As shown in FIG. 7, the second mask layer 400 covers the top surface of the laminated structure 200.

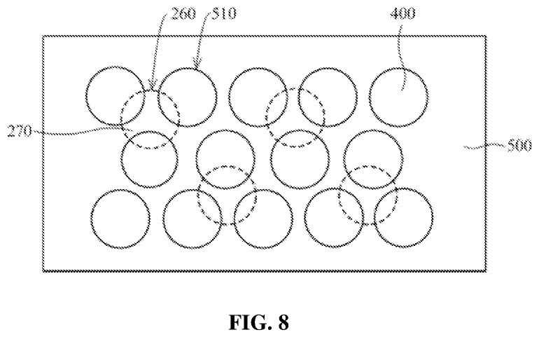

Referring to FIG. 7 and FIG. 8, after the second mask layer 400 is formed, a second photoresist layer 500 is formed on the second mask layer 400, and the second photoresist layer 500 has a second pattern. The second photoresist layer 500 is coated on the second mask layer 400 to form the second pattern with processes such as exposure and development. The second pattern may include multiple second openings 510 arranged at intervals and second shielding areas isolating each second opening 510. The second openings 510 expose the second mask layer 400. In a top view shown in FIG. 8, the second mask layer 400 is exposed in a circle shown by a solid line. The orthographic projections of the second openings 510 on the substrate 100 partly overlap with the orthographic projection of the sacrificial material 270 on the substrate 100, and the sacrificial material 270 located in one intermediate hole 260 corresponds to three second openings 510.

After the second photoresist layer 500 is formed, the second mask layer 400 is etched with the second photoresist layer 500 as a mask to form second etching holes penetrating through the second mask layer 400. The second mask layer 400 covered by the second photoresist layer 500 is retained, the second mask layer 400 not covered by the second photoresist layer 500 is removed, the second pattern of the second photoresist layer 500 is transmitted to the second mask layer 400, second etching holes are formed in the second mask layer 400, and the laminated structure 200 is exposed in the second etching holes.

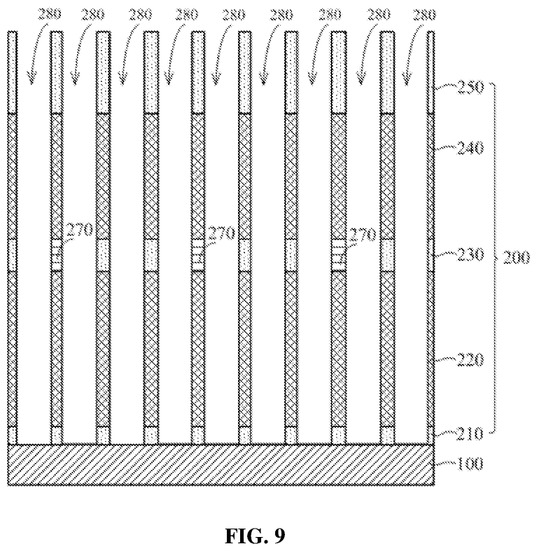

Referring to FIG. 9 and FIG. 10, after the second etching holes penetrating through the second mask layer 400 are formed, the laminated structure 200 is etched along the second etching holes to form capacitor holes 280 in the laminated structure 200. The capacitor holes 280 penetrate through the laminated structure 200 to expose the capacitor contactor (not shown in the figure) in the substrate 100. In the process of etching the capacitor holes 280, the second mask layer 400 will also be etched and removed at the same time. As shown in FIG. 9 and FIG. 10, after the capacitor holes 280 are formed, the second mask layer 400 is also completely removed, and the laminated structure 200 is exposed.

It is to be noted that, when the second mask layer 400 is etched, the second photoresist layer 500 will also be etched and removed at the same time. In some embodiments, after the second etching holes are formed, the second photoresist layer 500 is also completely removed, and the second mask layer 400 is exposed. In some other embodiments, after the second etching holes are formed, part of the second photoresist layer 500 is left, and the remaining second photoresist layer 500 may be removed by ashing or other processes to expose the second mask layer 400.

At S300, first polar plates are formed on the hole walls and the hole bottoms of the capacitor holes.

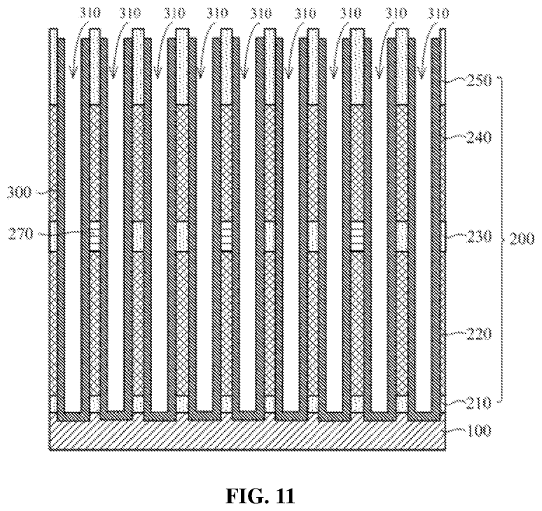

Referring to FIG. 11, the material of the first polar plates 300 may include conductive materials such as titanium nitride. The side parts of the first polar plate 300 are in contact with the laminated structure 200, and the bottoms of the first polar plates 300 are in contact with the capacitor contactors (not shown in the figure) in the substrate 100 to realize the electrical connection between the first polar plates 300 and the capacitor contactors.

Exemplarily, the first polar plates 300 may be formed with the following processes.

At first, a conductive layer is deposited on the hole walls and the hole bottoms of the capacitor holes 280, and on the laminated structure 200. The conductive layer located in each capacitor hole 280 forms a filling hole 310 in an encircling manner, so that a double-sided capacitor may be formed later to improve the capacity of the capacitor.

Secondly, the conductive layer located on the laminated structure 200 is removed by etching (such as dry etching), and the conductive layer located in the capacitor hole 280 is retained. The retained conductive layer forms the first polar plates 300. As shown in FIG. 11, the conductive layer on the top surface of the laminated structure 200 is removed, and the top surface of the laminated structure 200 is exposed.

At S400, an area corresponding to the intermediate holes in part of the supporting layers on the top layer of the laminated structure is removed to form capacitor opening holes, which expose the sacrificial layers.

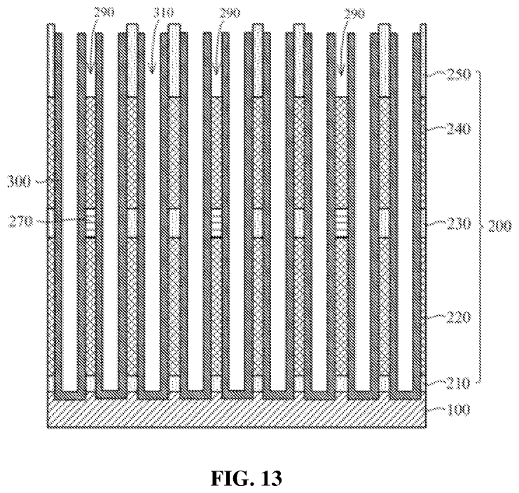

Referring to FIG. 13, part of the third supporting layer 250 on the top layer of the laminated structure 200 is removed to form capacitor opening holes 290 penetrating through the third supporting layer 250 so as to expose the second sacrificial layer 240. The capacitor opening holes 290 are opposite to the intermediate holes 260. Exemplarily, the width of the capacitor opening holes 290 is the same as that of the remaining sacrificial material 270, and the capacitor opening holes 290 expose part of the peripheral surfaces of the first polar plates 300. The peripheral surfaces refer to the surfaces of the first polar plates 300 in contact with the supporting layers, the sacrificial layers and the sacrificial material.

In some possible examples, the laminated structure 200 includes the first supporting layer 210, the first sacrificial layer 220, the second supporting layer 230, the second sacrificial layer 240 and the third supporting layer 250 which are stacked. The first supporting layer 210 is arranged on the substrate 100, and the second supporting layer 230 is provided with the intermediate hole 260. The area, corresponding to the intermediate holes 260, in the supporting layer on the top layer of the laminated structure 200 is removed to form the capacitor opening holes 290, and the capacitor opening holes 290 expose the sacrificial layers, which may include the following operations.

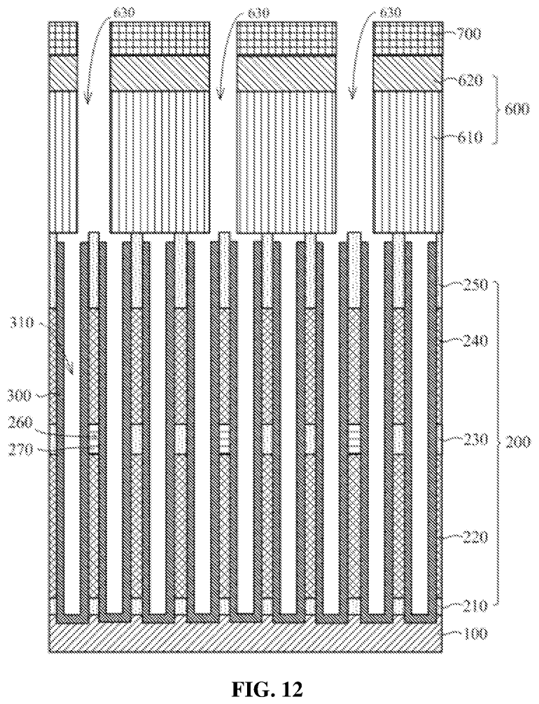

Referring to FIG. 12, a third mask layer 600 is formed on the laminated structure 200. Exemplarily, as shown in FIG. 12, the third mask layer 600 may include a second amorphous carbon layer (ACL) 610 and a second silicon oxynitride layer 620. The second ACL 610 is formed on the laminated structure 200. Specifically, the second ACL 610 is formed on the third supporting layer 250, and the second silicon oxynitride layer 620 is formed on the second ACL 610.

The second ACL 610 is formed by a deposition process. When the second ACL 610 is deposited, the second ACL 610 seals openings by controlling the deposition rate. That is, a relatively large deposition rate is adopted, so that the second ACL 610 is formed on the laminated structure 200 but not in the filling holes 310.

Continuously referring to FIG. 12, after the third mask layer 600 is formed, a third photoresist layer 700 is formed on the third mask layer 600, and the third photoresist layer 700 has a third pattern. The third photoresist layer 700 covers the top surface of the third mask layer 600, and the third pattern may include multiple third openings arranged at intervals (not shown in the figure) and third shielding areas isolating each third opening. The orthographic projections of the third openings on the substrate 100 at least cover the orthographic projections of the intermediate holes 260 on the substrate 100.

Continuously referring to FIG. 12, after the third photoresist layer 700 is formed, the third mask layer 600 is etched with the third photoresist layer 700 as a mask to form third etching holes 630 penetrating through the third mask layer 600. The third mask layer 600 covered by the third photoresist layer 700 is retained, and the third mask layer 600 not covered by the third photoresist layer 700 is removed. Third etching holes 630 are formed in the third mask layer 600 and the top surface of the laminated structure 200 and the top surfaces of the first polar plates 300 is exposed in the third etching holes 630.

Referring to FIG. 3, after the third etching holes 630 penetrating through the third mask layer 600 are formed, the laminated structure 200 is etched along the third etching holes 630 to remove the third supporting layer 250 exposed in the third etching holes 630. The capacitor opening holes 290 are formed in the third supporting layer 250 on the top layer of the laminated structure 200, and the second sacrificial layer 240 is exposed in the capacitor opening holes 290. In the process of etching the third supporting layer 250, the third mask layer 600 will also be etched and removed at the same time. As shown in FIG. 13, after the capacitor opening holes 290 are formed, the third mask layer 600 is also removed, and the remaining third supporting layer 250 and the first polar plates 300 are exposed.

It should be understood that, in the process of etching the third mask layer 600, the third photoresist layer 700 will also be etched and removed at the same time. After the third etching holes 630 are formed, if part of the third photoresist layer 700 still remains, the remaining third photoresist layer 700 may be removed by ashing or other processes to expose the third mask layer 600.

At S500, all the sacrificial layers and all the sacrificial material in all the intermediate holes are removed through the capacitor opening holes to expose the peripheral surfaces of the first polar plates.

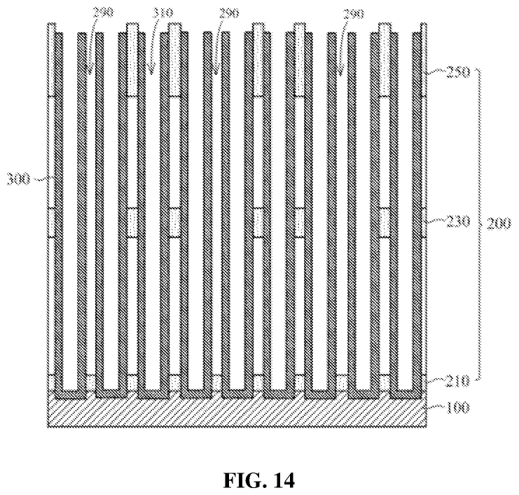

Referring to FIG. 14, etching gas or etching solution is introduced through the capacitor opening holes 290 to remove all the sacrificial layers and all the sacrificial material 270 so as to expose the peripheral surfaces of the first polar plates 300. As shown in FIG. 14, the sacrificial layers in contact with the first polar plates 300 are removed, and the capacitor opening holes 290 extend to the first supporting layer 210. That is, the sacrificial layers between the adjacent first polar plates 300 are removed, and the outer peripheral surfaces of the first polar plates 300 in contact with the sacrificial layers are exposed, so as to form a dielectric layer on the inner and outer peripheral surfaces of the first polar plates 300, thus form a double-sided capacitor. Herein, the inner peripheral surface refers to the surface, away from the supporting layer, the sacrificial layer and the sacrificial material, of the first polar plates 300.

In the embodiment of the disclosure, after the first polar plates 300 are formed, all the sacrificial layers and sacrificial material 270 are removed by one-time etching without opening the supporting layers layer by layer, which reduces the etching times of the supporting layers, reduces the possibility of damages of the first polar plates 300 by etching the supporting layers, and thus improves the yield of the memory. In addition, there is no need to alternately etch the sacrificial layers and the supporting layers, which also avoids the different etching processes caused by the different materials of the supporting layers and the sacrificial layers, and thus saves the time to change the etching processes, thereby reducing the etching time of the laminated structure 200 and improving the manufacturing efficiency of the memory.

It is to be noted that, after the operation of removing all the sacrificial layers and all the sacrificial material 270 in all the intermediate holes 260 through the capacitor opening holes 290 to expose the peripheral surfaces of the first polar plates 300, the method for manufacturing the memory according to the embodiment of the disclosure may also include the following operations.

Further referring to FIG. 14, a dielectric layer is formed on the exposed surfaces of the first polar plates 300. Exemplarily, the first polar plates 300 are cylindrical, the first polar plates 300 form filling holes 310, and the dielectric layer (not shown) covers the hole walls and hole bottom of the filling holes 310, the top surfaces of the first polar plates 300, and the peripheral surfaces of the first polar plates 300. The material of the dielectric layer may be a dielectric material with high dielectric constant, such as one or more of zirconia, hafnium oxide, antimony oxide, ruthenium oxide and alumina.

After a dielectric layer is formed, a second polar plate (not shown) is formed on the dielectric layer, and the first polar plates 300, the dielectric layer and the second polar plate constitute a capacitor. Part of the second polar plate is located in the filling holes 310 of the first polar plates 300, and part of the second polar plate is located in the space where the sacrificial layers and sacrificial material 270 are removed. The first polar plates 300, the dielectric layer and the second polar plate form a double-sided capacitor to improve the storage capacity of the capacitor.

In conclusion, according to the method for manufacturing the memory provided in the embodiment of the disclosure, the laminated structure 200 is formed on the substrate 100 at first, and the laminated structure 200 includes the sacrificial layers and the supporting layers arranged alternately. Herein, the number of the sacrificial layers is greater than 1. The top layer of the laminated structure 200 is the supporting layer, and a supporting layer between the two sacrificial layers is provided with the intermediate holes 260 filled with the sacrificial material 270; part of the laminated structure 200 is removed to form the capacitor holes 280 penetrating through the laminated structure 200; then, the first polar plates 300 are formed on the hole walls and the hole bottoms of the capacitor holes 280; the areas corresponding to the intermediate holes 260 in the supporting layer located on the top layer of the laminated structure 200 is removed to form the capacitor opening holes 290, which exposes a sacrificial layer; and all the sacrificial layers and all the sacrificial materials 270 in all the intermediate holes 260 are removed through the capacitor opening holes 290 to expose the peripheral surfaces of the first polar plates 300. The sacrificial layers and the sacrificial material 270 may be removed by one-time etching without opening the supporting layers layer by layer, which reduces the etching times and etching time of the supporting layers after the formation of the first polar plates 300, thereby reducing the possibility of damages to the first polar plates 300 and improving the yield of the memory.

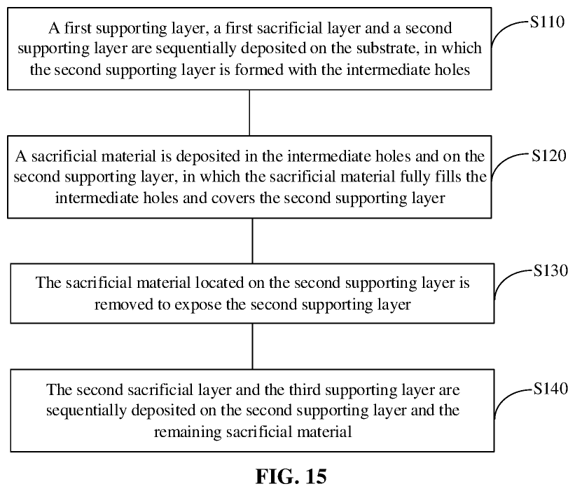

It is to be noted that, referring to FIG. 15 to FIG. 20, FIG. 15 is a flowchart for forming a laminated structure in the embodiment of the disclosure. The laminated structure 200 includes the first supporting layer 210, the first sacrificial layer 220, the second supporting layer 230, the second sacrificial layer 240 and the third supporting layer 250 which are stacked. The first supporting layer 210 is arranged on the substrate 100, and the second supporting layer 230 is provided with the intermediate holes 260. Correspondingly, the laminated structure 200 is formed on the substrate 100, which may include the following operations.

At S110, the first supporting layer, the first sacrificial layer and the second supporting layer are sequentially deposited on the substrate, and the second supporting layer is formed with intermediate holes.

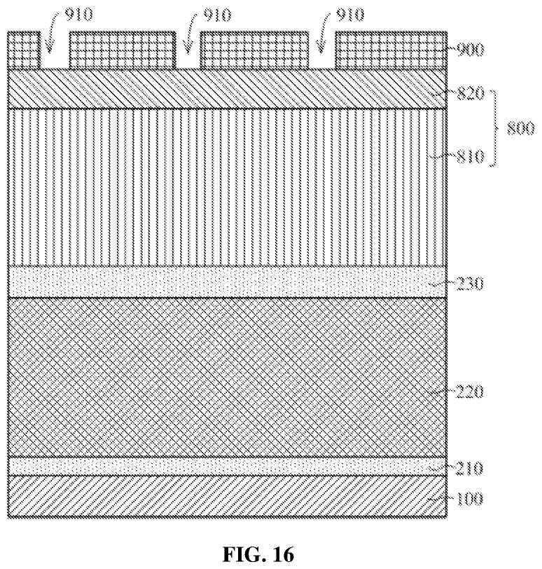

Exemplarily, referring to FIG. 16, firstly, a first mask layer 800 is formed on the second supporting layer 230. The first mask layer 800 covers the second supporting layer 230. As shown in FIG. 16, the first mask layer 800 may include a first ACL 810 and a first silicon oxynitride layer 820, the first ACL 810 is formed on the second supporting layer 230, and the first silicon oxynitride layer 820 is formed on the first ACL 810.

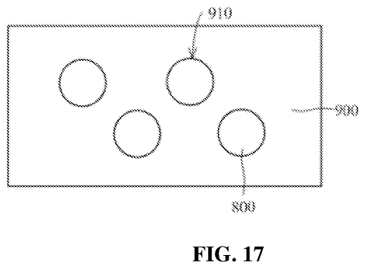

Secondly, a first photoresist layer 900 is deposited on the first mask layer 800, and the first photoresist layer 900 has a first pattern. Referring to FIG. 16 and FIG. 17, the first photoresist layer 900 covers the upper surface of the first mask layer 800, and the first pattern may include multiple first openings 910 arranged at intervals and a first shielding layer isolating each first opening 910. As shown in FIG. 17, the first mask layer 800 is exposed in the circular enclosed first openings 910, and the centers of the orthographic projections of the first openings 910 on the substrate 100 are located at the center of the virtual triangle surrounded by three capacitor contactors (not shown in the figure).

Afterwards, the first mask layer 800 is etched by taking the first photoresist layer 900 as a mask to form first etching holes penetrating through the first mask layer 800. The first mask layer 800 covered by the first photoresist layer 900 is retained, and the first mask layer 800 not covered by the first photoresist layer 900 is removed. First etching holes are formed in the first mask layer 800, and the second supporting layer 230 is exposed in the first etching holes.

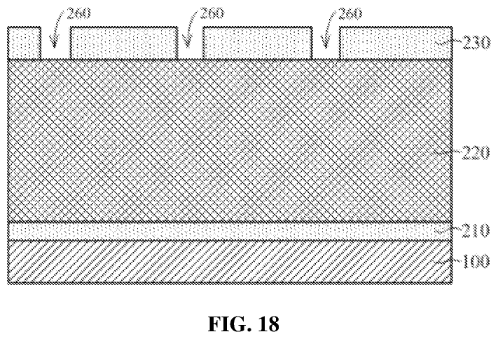

Then, the second supporting layer 230 is etched along the first etching holes to form intermediate holes 260. In the process of etching the second supporting layer 230, the first mask layer 800 will also be etched and removed at the same time. As shown in FIG. 18, after the intermediate holes 260 are formed, the first mask layer 800 is also completely removed, and the second supporting layer 230 is exposed.

It is to be noted that, when the first mask layer 800 is etched, the first photoresist layer 900 will also be etched and removed at the same time. After the first etching holes are formed, if part of the first photoresist layer 900 still remains, the remaining first photoresist layer 900 may be removed by ashing or other processes to expose the first mask layer 800.

At S120, the sacrificial material is deposited in the intermediate holes and on the second supporting layer, and the sacrificial material fills up the intermediate holes and covers the second supporting layer.

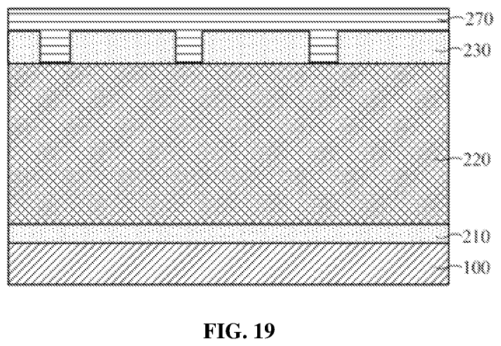

Referring to FIG. 19, the sacrificial material 270 may be a spin on dielectric (SOD). Exemplarily, the dielectric such as silicon oxide is spin coated in the intermediate holes 260 and on the second supporting layer 230. The sacrificial material 270 is in contact with the first sacrificial layer 220.

At S130, the sacrificial material on the second supporting layer is removed to expose the second supporting layer.

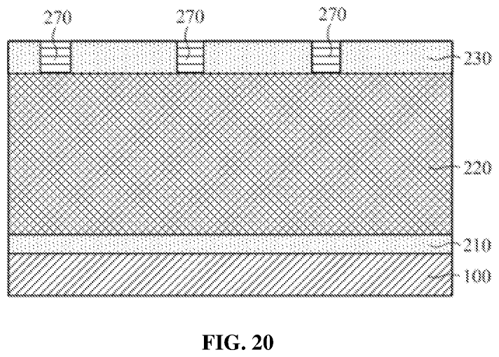

Referring to FIG. 20, the sacrificial material 270 in the intermediate holes 260 is retained, and the remaining sacrificial material 270 is removed. Exemplarily, the sacrificial material 270 located on the second supporting layer 230 is removed by dry etching, and the remaining sacrificial material 270 is aligned with the second supporting layer 230. The surface formed by the sacrificial material 270 and the second supporting layer 230 is relatively flat, so as to conveniently form other film layers on the second supporting layer 230. Certainly, the sacrificial material 270 located on the second supporting layer 230 may also be removed by a process such as chemical mechanical polishing (CMP).

At S140, the second sacrificial layer and the third supporting layer are sequentially deposited on the second supporting layer and the remaining sacrificial material.

Referring to FIG. 6, firstly, the second sacrificial layer 240 is deposited on the second supporting layer 230 and the remaining sacrificial material 270, and the second sacrificial layer 240 covers the second supporting layer 230 and the sacrificial material 270. Then, a third supporting layer 250 is deposited on the second sacrificial layer 240, and the third supporting layer 250 covers the second sacrificial layer 240 to form the laminated structure 200.

The embodiment of the disclosure also provides a memory. The memory is manufactured by the method for manufacturing the memory described above. The manufactured memory has the advantages of less damage to the first polar plates and relatively high yield of the memory. The specific effects are described above and will not be elaborated here.

Various embodiments or implementation modes in the specification are described in a progressive way. Each of the embodiments focuses on the differences from other embodiments, and same and similar parts among various embodiments may be referred to each other.

In description of the specification, description of referring terms such as “one embodiment”, “some embodiments”, “a schematic embodiment”, “an example”, “a specific example”, or “some examples” refers to specific features, structures, materials or features described in combination with the implementation modes or demonstrations involved in at least one implementation mode or demonstration of the disclosure. In the specification, schematic description on the above terms not always refers to same embodiment modes or demonstrations. Moreover, the described specific features, structures, materials or features may be combined in any one or more implementation modes or demonstrations in a proper manner.

Finally, it is to be noted that the above various embodiments are only used to illustrate the technical solutions of the disclosure, and are not limited thereto. Although the disclosure has been described in detail with reference to the foregoing various embodiments, those of ordinary skill in the art should understand that the technical solutions described in the foregoing various embodiments still may be modified, or part or all technical features are equivalently replaced, but the modifications and replacements do not make the essence of the corresponding technical solutions depart from the scope of the technical solutions of various embodiments of the disclosure.

1. A method for manufacturing a memory, comprising:
forming a laminated structure on a substrate, in which the laminated structure comprises sacrificial layers and supporting layers arranged alternately, wherein a number of the sacrificial layers is greater than 1, a top layer of the laminated structure is a supporting layer, and a supporting layer located between two sacrificial layers is provided with intermediate holes filled with a sacrificial material;
removing part of the laminated structure to form capacitor holes penetrating through the laminated structure;
forming first polar plates on hole walls and hole bottoms of the capacitor holes;
removing areas corresponding to the intermediate holes in the supporting layer of the top layer of the laminated structure to form capacitor opening holes, which expose an uppermost sacrificial layer; and
removing all the sacrificial layers and all the sacrificial material in all the intermediate holes through the capacitor opening holes to expose peripheral surfaces of the first polar plates.

2. The method for manufacturing a memory according to claim 1, wherein part of hole walls of the capacitor holes are located in the sacrificial material in the intermediate holes.

3. The method for manufacturing a memory according to claim 2, wherein there are a plurality of the intermediate holes 260 located in a same supporting layer, three capacitor holes are distributed in a circumferential direction of each intermediate hole, and the three capacitor holes are not communicated with each other.

4. The method for manufacturing a memory according to claim 1, wherein a material of the supporting layers is silicon nitride, a material of the sacrificial layers is silicon oxide, and the sacrificial material is silicon oxide.

5. The method for manufacturing a memory according to claim 1, wherein the laminated structure comprises a first supporting layer, a first sacrificial layer, a second supporting layer, a second sacrificial layer and a third supporting layer which are stacked, the first supporting layer is arranged on the substrate, and the second supporting layer is provided with the intermediate holes.

6. The method for manufacturing a memory according to claim 5, wherein said forming the laminated structure on the substrate, in which the laminated structure comprises the sacrificial layers and the supporting layers arranged alternately, comprises:
sequentially depositing the first supporting layer, the first sacrificial layer and the second supporting layer on the substrate, the second supporting layer being formed with the intermediate holes;
depositing the sacrificial material in the intermediate holes and on the second supporting layer, the sacrificial material fully filling the intermediate holes and covering the second supporting layer;
removing the sacrificial material located on the second supporting layer to expose the second supporting layer; and
sequentially depositing the second sacrificial layer and the third supporting layer on the second supporting layer and the remaining sacrificial material.

7. The method for manufacturing a memory according to claim 6, wherein said sequentially depositing the first supporting layer, the first sacrificial layer and the second supporting layer on the substrate, wherein the second supporting layer is formed with the intermediate holes, comprises:
forming a first mask layer on the second supporting layer;
forming a first photoresist layer on the first mask layer, the first photoresist layer having a first pattern;
etching the first mask layer by taking the first photoresist layer as a mask to form first etching holes penetrating through the first mask layer; and
etching the second supporting layer along the first etching holes to form the intermediate holes.

8. The method for manufacturing a memory according to claim 7, wherein the first mask layer comprises a first amorphous carbon layer (ACL) formed on the second supporting layer and a first silicon oxynitride layer formed on the first ACL.

9. The method for manufacturing a memory according to claim 6, wherein said removing the sacrificial material located on the second supporting layer to expose the second supporting layer comprises:
removing the sacrificial material located on the second supporting layer by dry etching, the remaining sacrificial material being flush with the second supporting layer.

10. The method for manufacturing a memory according to claim 5, wherein said removing part of the laminated structure to form capacitor holes penetrating through the laminated structure comprises:
forming a second mask layer on the laminated structure;
forming a second photoresist layer on the second mask layer, the second photoresist layer having a second pattern;
etching the second mask layer by taking the second photoresist layer as a mask to form second etching holes penetrating through the second mask layer; and
etching the laminated structure along the second etching holes, so as to form the capacitor holes in the laminated structure.

11. The method for manufacturing a memory according to claim 5, wherein said forming the first polar plates on the hole walls and the hole bottoms of the capacitor holes comprises:
depositing a conductive layer on the hole walls and the hole bottoms of the capacitor holes and on the third supporting layer; and
removing the conductive layer located on the third supporting layer by etching, and retaining the conductive layer located in the capacitor holes, the retained conductive layer forming the first polar plates.

12. The method for manufacturing a memory according to claim 5, wherein said removing the areas corresponding to the intermediate holes in the supporting layer on the top layer of the laminated structure to form the capacitor opening holes exposing the sacrificial layer comprises:
forming a third mask layer on the laminated structure;
forming a third photoresist layer on the third mask layer, the third photoresist layer having a third pattern;
etching the third mask layer by taking the third photoresist layer as a mask to form third etching holes penetrating through the third mask layer; and
etching the laminated structure along the third etching holes, so as to remove the third supporting layer exposed in the third etching holes.

13. The method for manufacturing a memory according to claim 12, wherein the third mask layer comprises a second ACL formed on the laminated structure and a second silicon oxynitride layer formed on the second ACL.

14. The method for manufacturing a memory according to claim 1, further comprising: after said removing all the sacrificial layers and all the sacrificial material in all the intermediate holes through the capacitor opening holes to expose the peripheral surfaces of the first polar plates,
forming a dielectric layer on the exposed peripheral surfaces of the first polar plates; and
forming a second polar plate on the dielectric layer, the first polar plates, the dielectric layer and the second polar plate constituting a capacitor.

15. A memory, manufactured by the method for manufacturing a memory according to claim 1.
